(19) United States
(12) Patent Application Publication
(10) Pub. No.: US 2025/0169364 A1
(43) Pub. Date: May 22, 2025

(54) PIEZOELECTRIC COMPONENT

(71) Applicant: TDK Electronics AG, Muenchen (DE)

(72) Inventors: Matthias Lischka, Deutschlandsberg (AT); Denis Orosel, Deutschlandsberg (AT); Markus Koini, Seiersberg (AT); Markus Puff, Graz (AT); Johann Pichler, Breitenau Am Hochlantsch (AT); Martina Kreuzbichler, Graz (AT)

(21) Appl. No.: 18/840,420

(22) PCT Filed: Feb. 23, 2023
(86) PCT No.: PCT/EP2023/054539

§ 371 Date: Aug. 21, 2024

(30) Foreign Application Priority Data
Mar. 1, 2022 (DE) 102022104838.1
Sep. 8, 2022 (DE) 102022122840.1

(51) Int. Cl. H10N 30/853; C04B 35/26; C04B 35/468; H10N 30/097

(52) U.S. Cl. CPC H10N 30/8561; C04B 35/26; C04B 35/4682; H10N 30/097; C04B 2235/3236; C04B 2235/3274

(57) ABSTRACT

In an embodiment a piezoelectric component includes a piezoelectric layer having a polycrystalline piezoelectric ceramic material with a coercive field strength of at least 1.8 kV/mm and a carrier element to which the piezoelectric layer is arranged and with which the piezoelectric layer is mechanically coupled.

### CROSS-REFERENCE TO RELATED APPLICATIONS

This patent application is a national phase filing under section 371 of PCT/EP2023/054539, filed Feb. 23, 2023, which claims the priority of German patent application 102022104838.1, filed Mar. 1, 2022, and German patent application 102022122840.1, filed Sep. 8, 2022, each of which is incorporated herein by reference in its entirety.

### TECHNICAL FIELD

The present invention concerns a piezoelectric component, the use of a lead-free ceramic in a piezoelectric component and a manufacturing method.

### BACKGROUND

Various applications such as haptic sensors and actuators, acoustic sensors and actuators, ultrasonic transducers or energy harvesting applications utilize the piezoelectric effect. The piezo elements required for this are usually made from variations of the ceramic material lead zirconium titanate (PbᵤZrᵥTi_{w}Oₓ), also known as PZT, as described, for example, in the German patent document DE 10 2009 030 710 A1.

Due to their material properties, however, the piezo elements must have a certain minimum physical thickness and be processed at great expense (high sintering temperatures, high material input).

These elements also contain high levels of the environmentally harmful heavy metal lead.

These disadvantageous properties can be compensated for by using alternative materials such as piezo-active plastics or lead-free piezoelectric ceramics.

### SUMMARY

Embodiments provide an alternative piezoelectric component with an improved piezoelectric layer.

Embodiments provide a piezoelectric component which comprises a piezoelectric layer which has a preferably polycrystalline ceramic material with a coercive field strength of at least 1.8 kV/mm and preferably between 2 and 10 kV/mm, more preferably between 2 and 5 kV/mm. Furthermore, the component comprises a carrier element to which the piezoelectric layer is applied and with which the piezoelectric layer is mechanically coupled. Consequently, the component is preferably designed in such a way that the carrier element and the piezoelectric layer deform together when stimulated.

The coercive field strength of the piezoelectric layer can correspond to the coercive field strength of the polycrystalline ceramic material.

The piezoelectric layer preferably has a layer thickness of at least 40 or at least 50 μm. The piezoelectric layer is preferably produced by means of a film process comprising film drawing and subsequent poling in an electric field.

In addition to piezoelectric layers with ceramics with a polycrystalline structure, embodiments with plastic-based piezoelectric layers or layers in which ceramic and plastic are combined are also possible. By optionally adding a piezoelectric plastic, the coercive field strength of the piezoelectric layer can be increased to up to 125 kV/mm.

No ceramic thin films are suitable for the piezoelectric layer, in particular no ceramic thin films having a structure similar to a single-crystal structure, which are produced for example by means of a sol-gel method or by means of chemical vapor deposition (for example CVD or ADL method), as these do not have sufficient mechanical stability in combination with the carrier element for the application examples mentioned below. The properties of such ceramic thin films, especially if they have a single-crystal-like structure, are dominated by the intracrystalline interactions that occur in the ceramic material, such as covalent or ionic bonds. As a rule, these are characterized by high coercive field strengths above 10 kV/mm, but also exhibit mechanical stresses within the ceramic thin film due to non-epitaxial growth.

In actuator and sensor applications in particular, the piezoelectric layer is exposed to considerable tensile or compressive forces that exceed the material properties of a ceramic thin film, especially a ceramic thin film with a monocrystalline structure. In particular, the ceramic thin film can crack along the mechanical stresses, rendering the component electrically and/or mechanically unusable.

Embodiments provide an improvement of piezoelectric layers with a ceramic having a polycrystalline structure. The coercivity of the piezoelectric layer with a polycrystalline structure depends primarily on intercrystalline interactions in the crystal lattice. Previously known piezoelectric layers with a ceramic with a polycrystalline structure generally have coercive field strengths of up to 3 kV/mm. By combining a suitable material and a suitable thin structure, it was possible to maximize the coercive field strength of the piezoelectric layer. At the same time, the properties of a polycrystalline ceramic layer, which are tolerant to mechanical stresses compared to ceramic thin films, could be maintained.

The material properties of piezoelectric ceramics with a monocrystalline structure or a structure similar to a monocrystal (material behavior resembles the behavior of a crystal, dominated by intracrystalline interactions) and piezoelectric ceramics with a polycrystalline structure (dominated by intercrystalline interactions) are therefore significantly different and not transferable.

Alternative components that concern piezoelectric ceramics with single-crystal structures are known, for example, from WO 2021/249844 A1 or US 2015/0 054 870 A1 or US 2006/0 119 229 A1.

During a film process to produce the piezoelectric layer, a raw material is provided as a powder in a first step. A green film is produced from the powder by adding binding agents and solvents, followed by mixing, film drawing and drying. Individual green parts can then be punched out of the film. Alternatively, the entire film can be further processed as a green part. The green part is then thermally processed and converted into a ceramic part. During thermal processing, the green part is preferably decarburized and sintered and then cooled.

In a subsequent extrinsic activation process, electrodes are applied to the ceramic part in order to pole the ceramic part and thus produce a piezoelectric layer with application-relevant piezoelectric functionality.

The poling is carried out, for example, in air or in a liquid/gaseous insulation medium at temperatures preferably between room temperature and 120° C. and at poling field strengths of 3.5 to 5 kV/mm, for example. For example, poling is carried out in air at 90° C. and at 3.5 kV/mm. The temperature during poling is therefore well below the Curie temperature of the piezoelectric layer.

The piezoelectric layer can then be applied to a carrier element. An actuator/sensor or transducer produced in this way can be operated in an electric field of up to 3 kV/mm and at temperatures between room temperature and 270° C., for example.

Stimulating of the piezoelectric layer can consist in particular of applying an electric field to the piezoelectric layer.

In this case, the piezoelectric layer deforms and with it the mechanically coupled carrier element, which thus acts as a mechanical actuator.

If the carrier element is mechanically deformed, e.g. by mechanical pressure or sound waves, the piezoelectric layer mechanically coupled to it is also deformed so that an electrical signal is generated. The component then acts as a sensor.

In both cases, the component acts as a converter between mechanical and electrical energy.

In one embodiment, two different electrodes can be applied to the surfaces of the piezoelectric layer. In operation, the two electrodes have different polarities when a voltage is applied.

The electrodes can be used to apply an electric field to the piezoelectric layer or to pick up an electrical signal, in particular an electrical voltage, from the piezoelectric layer.

Applying an electric field to the piezoelectric layer can, in particular, lead to mechanical deformation of the layer. On the other hand, an electrical signal to be picked up can be generated by applying mechanical force to the piezoelectric layer.

Advantageously, the two electrodes are disk-shaped and applied to opposite surfaces of the piezoelectric layer. In particular, the two electrodes can be applied over the entire surface so that an electric field can be applied or tapped that extends over the entire thickness of the piezoelectric layer. In one embodiment, the electrodes do not completely cover the opposing surfaces, but a free edge, i.e. a section free of the electrodes, is formed on the surfaces around the electrodes.

Preferably, the piezoelectric layer and at least one of the electrodes are circular disk-shaped. The radius of the circular disk-shaped piezoelectric layer and that of the circular disk-shaped electrode can be of the same or different sizes. Preferably, the radius of the circular disk-shaped electrode is up to 500 μm smaller than the radius of the circular disk-shaped piezoelectric element.

In one embodiment, at least one of the electrodes extends over the side surface and optionally also over the opposite surface of the piezoelectric layer, so that the electrode is applied to both of the opposite surfaces. This means that the electrode can be electrically connected from both sides. In one embodiment, both electrodes can be designed accordingly. However, the electrodes must not be in direct contact with each other.

The carrier element, which can be designed as a membrane, is preferably electrically conductive and comprises an electrically conductive material, for example a metal such as brass, aluminum, titanium, copper or a steel, a carbon fiber material, etc. Alternatively, the carrier element can also comprise a plastic material or glass fibre reinforced plastic (GRP), for example, which is metallized on the surface or which contains conductive particles.

Preferably, the piezoelectric layer or one of the electrodes on the surface of the piezoelectric layer is friction-locked to the carrier element.

In one embodiment, the piezoelectric layer or one of the electrodes on the surface of the piezoelectric layer is bonded to the carrier element. For example, a bonding layer made of an adhesive material is provided between the piezoelectric layer and the carrier element. The adhesive material can be electrically non-conductive, anisotropically conductive, i.e. preferably conductive in one direction between the carrier element and the electrode and non-conductive perpendicular to it, or conductive.

In one embodiment, the piezoelectric layer and the electrodes applied to it are designed as circular or elliptical disks. Alternatively, the piezoelectric layer and the electrodes applied to it are designed as a 3-, 4-, 5-, 6- or n-corner (n is here a natural number >6).

Preferably, the piezoelectric component further comprises a carrier element, for example a membrane, to which the piezoelectric layer can be applied. Like the piezoelectric layer, the membrane can be circular or have a different geometry to the piezoelectric layer.

The carrier element or membrane is preferably one of the electrodes applied to a surface of the piezoelectric layer. The carrier element can have electrically conductive properties for this purpose. The carrier element and the piezoelectric layer are bonded by soldering, welding, gluing, preferably with an electrically conductive adhesive, or by joint sintering, for example.

External electrical stimulating, in particular the application of an electric field, for example via electrodes applied to the surface of the piezoelectric layer, leads for example to a contraction or expansion of the layer due to the piezoelectric effect. For the vast majority of applications, a directed contraction or expansion in the direction of the layer thickness or perpendicular to it in the direction of a layer plane is preferred. In principle, however, contraction or expansion in any other direction is also possible with the solution presented here, whereby this is largely determined by the geometry of the layer.

For this purpose, an electric field is applied to the piezoelectric layer, causing it to change its expansion. For example, an electrical voltage is applied to the electrodes applied to two surfaces of the layer.

The force acting on a carrier element, such as a membrane, due to the change in the expansion of the piezoelectric layer leads to a bending moment and causes a movement perpendicular to the base surface of the component, which is used for the desired applications.

In particular, the application of an electric field to the piezoelectric layer causes the piezoelectric layer to change its expansion. Preferably, the expansion changes in the layer plane of the piezoelectric layer.

For example, in the case of a circular piezoelectric layer plane, the diameter of the piezoelectric layer can change. In particular, the diameter of the piezoelectric layer changes when the circular piezoelectric layer is operated as a radial oscillator. The coupling of the piezoelectric layer with the carrier element then results in a deflection of the composite of piezoelectric layer and carrier element in a direction perpendicular to the layer plane of the piezoelectric layer. This means that the expansion of the piezoelectric layer applied to the carrier element leads to a bending moment that causes the carrier element to deflect in a direction perpendicular to the layer plane of the piezoelectric layer.

A maximum deflection of the carrier element with a diameter D in a direction z perpendicular to the layer plane thus depends both on the properties of the piezoelectric layer, in particular the thickness of the piezoelectric layer tₚ, the piezoelectric constant d31, the Poisson's ratio v as a characteristic number for the transverse contraction and the modulus of elasticity (Young's modulus) Eₚ of the piezoelectric layer as well as the properties of the support element, in particular the thickness of the support element the and the Young's modulus of the support element E_{c}.

In particular, the maximum deflection A_{displacement} in the z-direction can be determined to a good approximation using the following formula:

$${A}_{displacement} ( Z ) = \frac{{D}^{2}}{8} \frac{6 {E}_{p} {E}_{c} {t}_{p} {t}_{c} ( {t}_{p} + {t}_{c} ) {d}_{31} E ( 1 - v )}{{E}_{p}^{2} {t}_{p}^{4} + {E}_{c}^{2} {t}_{c}^{4} + 2 {E}_{p} {E}_{c} {t}_{p} {t}_{c} ( 2 {t}_{p}^{2} + 2 {t}_{c}^{2} + 3 {t}_{p} {t}_{c} )}$$

In particular, the form-fitting and materially connection of the piezoelectric layer and the carrier material by means of e.g. adhesives enables the sensor/actuator/transducer etc. to be viewed as a composite.

Due to the above-mentioned analytical correlation and the resulting interaction of the individual components with each other, the required electromechanical properties must be adapted by changing, for example, the geometry or the substrate material. This means that not only the properties of the ceramic, but also the interactions mentioned are responsible for the working behavior of the actuator/sensor/transducer etc.

For an application as a sensor, the situation described above for an application as an actuator applies in reverse. This means that a bending moment caused by a force applied along the vertical axis generates a measurable electrical voltage in the piezoelectric layer, which can be read or tapped accordingly.

In order for the component consisting of piezoelectric layer and carrier element to achieve a deflection from a rest position, the neutral phase of the component composite should be located within the piezoelectric layer. The neutral phase is defined as the imaginary line that does not undergo any deformation.

This is influenced in particular by the following variables and ratios, which must therefore be suitably selected: Thickness and diameter of the layer, thickness and diameter of the carrier element, ratio of thicknesses of layer and carrier element, ratio of diameters of layer and carrier element, center-to-center distance of layer and carrier element, Young's modulus of layer and carrier element, Poisson's ratio of layer and carrier element, 3D geometry of layer and carrier element, acoustic impedance of layer and carrier element, spring contour of layer and carrier element, and thickness and elastomechanical properties of a connecting layer between carrier element and piezoelectric layer.

The component is preferably a radial oscillator.

The difference between a radial and a thickness oscillator consists essentially in the different dimensional ratios of diameter to thickness.

A ratio of diameter/thickness of the piezoelectric layer of a radial oscillator is diameter/thickness >10 or equal to 10. A ratio of diameter/thickness of the piezoelectric layer of a thickness oscillator is diameter/thickness <10.

In a radial oscillator, the diameter of the piezoelectric layer changes in relation to the original diameter when an electrical voltage is applied. This is represented by the piezoelectric constant d31.

In order to generate a movement in the direction of the thickness of the piezoelectric layer, a carrier material is required as described above. The carrier material and the component consisting of piezoelectric layer and carrier material are optimized for the respective application, e.g. with regard to charge generation, impedance and/or deflection.

The behavior of thickness oscillators, on the other hand, is described by a piezoelectric constant d33 and the applied electrical voltage. Here, the ceramic is compressed or stretched directly in the direction of the thickness. Thickness oscillators therefore do not require a carrier material and can be used independently. An example of a thickness oscillator is given in EP 3 372 571 B1, for example.

Due to its composite nature, the radial oscillator can be used for a wider range of applications. As described, radial oscillators can be used as actuators, sensors or converters, for example.

In addition to the position of the neutral phase, the following properties of a piezoelectric component are also influenced by the above-mentioned variables: permissible actuation voltage, resonant frequencies, permissible compressive and tensile stresses for the ceramic, blocking force, quality, impedance, capacitance and charge generation, acoustic impedance, spring properties, mechanical damping, the efficiency of the “electrical-mechanical” conversion, the efficiency of the “mechanical-electrical” conversion as well as deflection and acceleration.

In particular, the piezoelectric layer described is characterized by the aforementioned high coercive field strength, so that the thickness of the piezoelectric layer in the piezoelectric component can be reduced while the requirements remain otherwise unchanged. This means that the amount of material used in the production process can be reduced by around 30 percent while maintaining the same functionality of the component. This leads to lower manufacturing costs and less raw material consumption.

Thus, the piezoelectric layer described is preferably suitable for the production of thin piezoelectric components.

A polycrystalline, piezoelectric ceramic material with a high coercive field strength is thus preferably used to form the piezoelectric layer. The coercive field strength of the piezoelectric layer can correspond to the coercive field strength of the polycrystalline, piezoelectric ceramic material. The coercive field strength of the piezoelectric layer can be increased to up to 125 kV/mm by adding a piezoelectric plastic.

Furthermore, the sintering temperature for producing the described polycrystalline piezoelectric ceramic material from a green layer is low, so that its production can be carried out with less energy input and thus more cost-effectively.

The sintering temperature is, for example, less than 1050° C., preferably less than 1030° C. The sintering temperature is also preferably more than 900° C. and in particular between 900° C. and 1030° C.

The sintering temperature of the piezoelectric layer can correspond to the sintering temperature of the polycrystalline piezoelectric ceramic material.

This makes the green layer particularly suitable for application and subsequent joint sintering with carrier elements or membranes that are sensitive to higher temperatures.

The green layer described is also suitable for forming ceramic foils, so that a piezoelectric layer with a desired low layer thickness can be realized simply by foil technology, i.e. by stacking and pressing prefabricated foils. The piezoelectric layer can also comprise only one film with a corresponding thickness. By using a single thick film, stacking and pressing can be dispensed with, which simplifies the manufacturing process. In this case, machining methods such as grinding or lapping to achieve a target value for the thickness can be dispensed with. This enables further material and resource savings in the manufacturing process and reduces the number of work steps required.

In a preferred embodiment, the electromechanical coupling factor k31 of the polycrystalline piezoelectric ceramic material is between 0.2 and 0.3, preferably between 0.25 and 0.3, particularly preferably 0.27. The electromechanical coupling factor k31 of the piezoelectric layer can correspond to the electromechanical coupling factor k31 of the polycrystalline piezoelectric ceramic material.

In another preferred embodiment, the density of the polycrystalline piezoelectric ceramic material is between 7000 and 7500 kg/m³. The density of the piezoelectric layer can correspond to the density of the polycrystalline piezoelectric ceramic material.

In a further preferred embodiment, the relative dielectric constant in the poling direction or permittivity number εᵣ=833/80 of the polycrystalline piezoelectric ceramic material is less than 1100, preferably less than 1000, particularly preferably between 800 and 1100, more preferably between 900 and 1000, more preferably between 910 and 950. The permittivity number εᵣ of the piezoelectric layer can correspond to the permittivity number εᵣ of the polycrystalline piezoelectric ceramic material. By adding a piezoelectric plastic, the permittivity number εᵣ of the piezoelectric layer can be reduced to up to 8.

In a further preferred embodiment, the piezoelectric constant of the polycrystalline piezoelectric ceramic material d31 is less than 100 pm/V, preferably between 50 and 100 pm/V, preferably between 70 and 90 pm/V. The piezoelectric constant d31 of the piezoelectric layer can correspond to the piezoelectric constant d31 of the polycrystalline piezoelectric ceramic material. The piezoelectric constant of a piezoelectric layer made of a piezoelectric plastic such as PVDF (polyvinylidene fluoride) is approximately 10 to 12 pm/V. By adding a piezoelectric plastic, the piezoelectric constant d31 of the piezoelectric layer can thus be further reduced.

In a further preferred embodiment, the Curie temperature of the polycrystalline piezoelectric ceramic material is between 40° and 500° C. The Curie temperature of the piezoelectric layer can correspond to the Curie temperature of the polycrystalline piezoelectric ceramic material.

In a further preferred embodiment, the mechanical quality Qm of the polycrystalline piezoelectric ceramic material is between 50 and 100, preferably between 50 and 70, more preferably 60. The mechanical quality Qm of the piezoelectric layer can correspond to the mechanical quality Qm of the polycrystalline piezoelectric ceramic material.

In a further preferred embodiment, the carrier element has a modulus of elasticity E of between 0.1 and 1000 GPa, preferably between 60 and 215 GPa, more preferably between 100 and 180 GPa.

A ratio between the modulus of elasticity of the carrier element and the modulus of elasticity of the piezoelectric layer is preferably between 0.0004 and 3000. In this way, a desired mechanical interaction between the carrier element and the piezoelectric layer can be achieved. A deformation of the carrier element results in a corresponding deformation of the piezoelectric layer and vice versa.

The piezoelectric layer is preferably free of internal structural elements such as internal electrodes or metallization layers.

In a preferred embodiment, the piezoelectric layer comprises a ceramic material with a composition (BiₓFeO₃)₁₋ₐ(Ba_{y}TiO₃)ₐ, where 0.20≤a≤0.50; 0.90≤x≤1.10 and 0.90≤y≤1.01. The piezoelectric layer can essentially be formed from this ceramic material or consist of it. Preferably, the ceramic material is a polycrystalline piezoelectric ceramic.

The ceramic material or the entire piezoelectric layer or the entire piezoelectric component is preferably lead-free.

The term lead-free is used here and in the following to refer in particular to a material that contains less than 0.1% lead (Pb) by mass in accordance with the EU's Restriction of Hazardous Substances (RoHS) Directive of 2011.

In preferred embodiments, lead-free is understood to mean an even significantly lower lead content or no lead content at all.

The use of lead-free ceramic material in piezoelectric components makes it possible to produce components without using the environmentally harmful and toxic heavy metal lead. In particular, this also enables new applications, for example in consumer products and medical technology products.

Furthermore, the properties of the piezoelectric components described are very similar to those of conventional piezoelectric components based on leaded PZT ceramics. With a suitable dimensioning of the piezoelectric layer of the electrodes and a coupled carrier element, the piezoelectric component described can be used like conventional piezoelectric components.

In particular, the ceramic material described is characterized by a high coercive field strength, so that the thickness of the piezoelectric layer in the piezoelectric component can be reduced while the boundary conditions remain otherwise unchanged. This means that the amount of material used in the production process can be reduced by around 30 percent while the functionality of the component remains the same. This leads to lower manufacturing costs and less raw material consumption.

Thus, the described polycrystalline ceramic material is preferably suitable for the production of thin polycrystalline piezoelectric layers or thin polycrystalline piezoelectric components.

Furthermore, the sintering temperature of the described ceramic material without lead is lower than that of conventional ceramics with lead, so that the ceramic layer can be produced with less energy input and thus more cost-effectively.

As the component volume and mass are also reduced compared to components containing lead, the amount of material to be heated in the sintering furnace is also reduced in addition to the lower sintering temperature, making the process more economical. This means that the load of the sintering furnace can either be increased with the same space utilization or only a smaller mass needs to be heated to the required sintering temperature with the same load.

In a preferred embodiment, the composition of the ceramic material is 0.25≤a≤ 0.40; 0.99≤x≤1.05 and 0.95≤y≤1.005.

In another preferred embodiment, the composition of the ceramic material is 0.28≤ a≤0.36; 0.99≤x≤1.05 and 0.975≤y≤1.005.

Such a ceramic material has particularly preferred properties. In particular, the ceramic material has suitable piezoelectric properties to be able to replace lead-containing or plastic-containing ceramic layers of various, and in particular thin piezoelectric components with variable applications.

The piezoelectric properties considered here include the piezoelectric constant, the relative dielectric constant, the electromechanical coupling factor, the coercive field strength, the Curie temperature and the density of the ceramic material.

In particular, the lead-free piezoelectric ceramic material preferably has a piezoelectric constant of at least 75 pm/V, a relative dielectric constant of at least 1000, an electromechanical coupling factor of at least 0.25; a coercive field strength of 1.8 kV/mm or more, a Curie temperature above 400° C. and a density above 7000 kg/m³ due to its composition.

According to one embodiment, the piezoelectric layer is free of plastics as a further ingredient. In particular, the piezoelectric layer preferably consists of inorganic materials comprising the ceramic material.

The piezoelectric layer thus has a high density, stability and strength. In particular, the piezoelectric layer exhibits these properties to a greater extent than a piezoelectric plastic layer.

According to one embodiment, the piezoelectric layer does not contain any ingredients other than those mentioned.

Preferably, the piezoelectric layer consists of the ceramic material.

Such a piezoelectric layer has the aforementioned advantageous properties of the ceramic material and is, in particular, free of lead.

According to further embodiments, the piezoelectric layer comprises a piezoelectric plastic. In particular, the piezoelectric layer may comprise a piezoelectric plastic and a ceramic, preferably one of the aforementioned ceramic materials.

Plastic-based coatings have a high degree of flexibility and frequency-dependent deformation. However, there are limits to the use of pure piezoelectric plastics such as PVDF for actuator/sensor/transducer applications due to their mechanical and thermal stability.

Disadvantageous properties of piezoceramics and plastics can be compensated for by combining them as a composite material. For example, a sintered piezoceramic powder or sintered preformed ceramics, e.g. wires, can be added to a plastic matrix. The mechanical, electrical and electromechanical properties of the composite material can thus be adjusted within the framework of the properties of the individual components in relation to the mixing ratio of the components, i.e. plastic and ceramic.

Piezoelectric layers can be produced from such ceramic-plastic composite materials using manufacturing processes such as film drawing or pressing.

According to one embodiment, the thickness of the piezoelectric layer is at least 40 or at least 50 micrometers (μm).

According to one embodiment, the layer thickness of the piezoelectric layer is a maximum of 150 μm.

Preferably, the layer thickness of the piezoelectric layer is a maximum of 140 μm, more preferably a maximum of 130 μm.

When used as an ultrasonic transducer, the thickness is preferably between 70 and 130 μm. In a haptic application, the thickness is preferably a maximum of 105 μm.

Such a thin layer thickness reduces the amount of material required and the costs of the manufacturing process and enables new applications for the piezoelectric component.

According to one embodiment, the layer thickness of the associated green layer before sintering is at least 50 μm.

According to one embodiment, the layer thickness of the green layer is a maximum of 210 μm and preferably between 120 and 160 μm.

For a process in which several green films are stacked and pressed to form a green layer, the thickness of the individual green films is preferably between 30 and 130 μm, particularly preferably 80 μm.

In particular, by designing the piezoelectric layer with such a low layer thickness, a thin piezoelectric component can be provided that is free of lead. The thin component has a low material consumption during manufacture and a low space consumption when installed in the intended application device. This means that miniaturized sensors and actuators can be advantageously provided for use in computer housings, smartphones or for automated and automotive applications, for example.

Such a thin piezoelectric component comprises exactly one piezoelectric layer with the described layer thickness and electrodes applied to it, which preferably also have a low layer thickness in the micrometer range.

The piezoelectric component can be configured in such a way that it can be used in a wide variety of applications.

Preferably, the entire piezoelectric component can be lead-free. This means that the component does not contain any lead-containing components even outside the piezoelectric layer, just as it does inside the piezoelectric layer. This means that the use of lead, which has toxic and environmentally hazardous properties, can be avoided and legal regulations regarding the avoidance of the use of lead can be complied with.

Preferably, in one embodiment, the piezoelectric component further comprises a carrier element to which the piezoelectric layer is applied as described above. The carrier element may be a membrane. The carrier element can be one of the electrodes applied to a surface of the piezoelectric layer. It is possible, for example, to conductively connect the piezoelectric element to a conductive carrier element on one side (e.g. by gluing or soldering). In this case, the carrier element is also the electrode. In addition, the described joining agent can be present between the carrier element and the piezoelectric layer.

In other embodiments, the piezo element may already have an electrode (e.g. by sputtering on a metal layer). This electrode is then connected to the conductive carrier element by a conductive connection (analogous to the previous example).

In one embodiment, the component comprises the carrier element and the piezoelectric layer. Preferably, the piezoelectric layer is designed as an elliptical or circular disk, which is applied to a carrier element that is also disk-shaped and preferably has a larger surface area.

Preferably, a ratio of the diameter of the circular piezoelectric layer to the diameter of the circular support element is between 0.3 and 1.0, more preferably between 0.55 and 0.73, more preferably between 0.6 and 0.7, in each case including the respective limit values.

This allows the interaction between the piezoelectric layer and the carrier element to be optimized depending on the application.

Alternatively, the shape of the disks can also be polygonal instead of round. The dimensions of the surface of the disk-shaped support element and the piezoelectric layer are significantly larger than their thicknesses.

A first electrode is applied as a thin film to a surface of the piezoelectric layer that faces away from the carrier element. The carrier element can then represent the second electrode. Alternatively, a second electrode can be provided as a thin layer between the piezoelectric layer and the carrier element. A thin layer of a bonding material, such as an adhesive or solder, can also be provided between the electrode and the carrier element. Alternatively, the bonding layer can be a metallic layer produced by transient liquid phase sintering, silver sintering or a similar method.

In one embodiment, the dimensions of the individual layers of the component described have the same order of magnitude as the dimensions of the piezoelectric layer and are preferably in the micrometer range.

The piezoelectric component is preferably a thin polycrystalline component. The direction in which the individual layers of the component are stacked on top of each other is referred to as the stacking direction. The thickness of the component in the stacking direction, comprising the layers described above, is preferably in the micrometer range.

In a preferred embodiment, the piezoelectric component comprises exactly one piezoelectric layer. Preferably, the piezoelectric component comprises exactly once the above-described layer sequence of the first electrode, the piezoelectric layer and the second electrode, preferably in the form of the carrier element, and optionally a carrier element. The component preferably comprises no further layers. The piezoelectric component is thus as thin as possible.

The piezoelectric component can be designed in various embodiments, in particular as a component for use as a haptic actuator, haptic sensor, buzzer, ultrasonic transducer, ultrasonic transmitter or ultrasonic receiver, micropump for fluids, energy harvester or particle detector. Examples of such designs are described in detail below.

In particular, in one embodiment, the piezoelectric component can be designed for use as a haptic actuator, which is suitable for generating a mechanical deformation of the carrier element from an electrical signal applied to the piezoelectric layer.

By suitably adapting the control electronics using the increased coercive field strength, in particular the increased coercive field strength of the lead-free ceramic compared to a lead-containing ceramic, the thickness of the piezoelectric layer and the component can be reduced without reducing the quality of the haptic signal.

The deflection of a piezoelectric actuator with a thin piezoelectric layer, which has a high coercive field strength, is equal to the deflection of an actuator with a thicker piezoelectric layer with a lower coercive field strength when controlled accordingly. The coercive field strength of the piezoelectric layer is between 1.5 and 10 kV/mm.

In particular, the piezoelectric layer may be suitable for being subjected to a DC voltage of at least 50 volts and a tip-to-peak voltage of at least 700 volts due to its high coercive field strength.

By increasing the coercive field strength of the piezoelectric layer made of lead-free ceramic compared to a lead-containing ceramic, a functionally equivalent and thinner, i.e. space-saving, component can be produced while saving material.

In particular, in a further embodiment, the piezoelectric component can be designed for use as a haptic sensor, which is suitable for generating an electrical signal that can be picked up at the piezoelectric layer from a mechanical deformation of the carrier element. The component can also be designed for use as a haptic actuator and sensor.

By suitably adapting the evaluation electronics using the increased coercive field strength, in particular the increased coercive field strength of the lead-free ceramic, the thickness of the piezoelectric layer and the component can be reduced without reducing the quality of the measured electrical signal.

The electrical signal of a piezoelectric sensor with a thin piezoelectric layer, which has a high coercive field strength, is similar to the signal of a sensor with a thicker piezoelectric layer with a lower coercive field strength when suitably controlled. The coercive field strength of the piezoelectric layer is between 1.5 and 10 kV/mm.

By increasing the coercive field strength of the piezoelectric layer, a functionally equivalent and thinner, i.e. space-saving, component can be produced while saving material. In another embodiment, the piezoelectric component is designed for use as a buzzer.

A buzzer is an actuator that generates sound from an electrical signal, in other words a sound transmitter.

Essentially, the buzzer is a haptic actuator that deforms at a certain frequency to generate sound waves in the audible range.

For example, the minimum requirement can be defined as a sound pressure of at least 75 decibels at a distance of 10 cm from the outer side of the buzzer membrane. Due to the high coercive field strength of the lead-free piezoelectric layer, a piezoelectric layer with a low thickness of maximum 120 μm is sufficient to generate the required sound pressure with suitable control. Preferably, the thickness of the layer is between 80 and 120 μm, more preferably a maximum of 105 μm, more preferably a maximum of 100 μm or less than 100 μm.

The thickness of the membrane is then preferably between 25 μm and 125 μm.

Preferably, the diameter of the layer is between 5 mm and 14 mm inclusive.

With these dimensions, the buzzer can cover at least a frequency range of 2 kHz to 8 kHz.

By increasing the coercive field strength of the piezoelectric layer, a functionally equivalent and thinner, i.e. space-saving, component can be produced while saving material.

The piezoelectric layer is designed in particular so that the buzzer reaches the maximum sound pressure when stimulated by an electrical signal with a voltage of up to 3 volts and an electrical frequency of 4 kHz.

In a further embodiment, the piezoelectric component is designed for use as an ultrasonic transducer or ultrasonic transmitter or ultrasonic receiver.

The ultrasonic transducer can both generate an ultrasound from an electrical signal (ultrasonic transmitter) and, conversely, generate an electrical signal from an ultrasound (ultrasonic receiver).

Essentially, the ultrasonic transducer is a haptic actuator or sensor that deforms at a certain frequency in order to generate or detect sound waves in the ultrasonic range. As a rule, such an ultrasonic transducer is used for distance measurement. Furthermore, the ultrasonic transducers can also be used for other applications, e.g. for transmitting energy and/or data, particularly through metal.

As a minimum requirement, a sufficiently high sound pressure can be defined here, which is suitable for detecting objects at a distance of up to 200 cm.

Due to the high coercivity of the lead-free piezoelectric layer, a piezoelectric layer with a low thickness of between 70 and 130 μm is sufficient to generate the required sound pressure with suitable control. The preferred diameter of the layer is 5 mm to 14 mm or 5 to 7 mm.

For example, the piezoelectric layer preferably has the following properties. At an applied AC voltage of 1 volt and a frequency of 1 kHz, the capacitance C of the piezoelectric layer is between 0.9 and 1.0 nF. The dielectric loss 8 is between 0.05 and 0.15, preferably 0.10. The permittivity & is between 800 and 900. The piezoelectric constant d33 is between 100 and 200 pC/N. The effective coupling k_{eff} is between 0.2 and 0.3.

The natural frequency of the piezoelectric layer is, for example, between 450 and 550 kHz, preferably 500 kHz.

At an AC voltage of 0.1 volts and at the resonance frequency of the ceramic, the capacitance C is between 0.5 and 0.7 nF, for example. The permittivity & is then between 400 and 500.

In another embodiment, the piezoelectric component is designed as a micropump for fluids. Several haptic actuators are used in such a micropump. The haptic actuators form the lids of microchambers that can hold fluids.

By deforming such a haptic actuator, fluid can be displaced from a microchamber so that a pumping effect is generated. By using the advantageous components described with a thin piezoelectric layer, the size of the micropump can be reduced and the amount of material required to manufacture the micropump can be optimized.

In a further embodiment, the piezoelectric component is designed for use as a particle detector.

The piezoelectric component is installed in a flow channel for this purpose. For example, a gas that transports solid particles can be conveyed in the flow channel.

In the operating state, the piezoelectric layer of the component is stimulated to oscillate at a frequency in the ultrasonic range.

If a solid particle hits a membrane of the piezoelectric component, the piezoelectric layer coupled to it deforms and causes a change in the oscillation frequency. The change in the oscillation frequency depends on the size and number of particles, which can therefore be determined by the evaluation electronics.

By using the advantageous components described with a thin piezoelectric layer, the size of the particle detector can be reduced and the amount of material required to manufacture the particle detector can be optimized.

In the aforementioned applications, the piezoelectric component can replace a conventional piezoelectric component comprising a lead-containing and/or a plastic-containing piezoelectric material without having to make any compromises in terms of functionality.

Embodiments provide a method for manufacturing a piezoelectric component with a piezoelectric layer, which can have all the features of the component described above.

Conversely, the features described below can also apply to all of the above-mentioned embodiments.

The method comprises several steps. One step comprises providing green films. Preferably, the green films are produced by film drawing. This produces very homogeneous but thin films. The individual films preferably have a maximum thickness of 80 μm.

A further step comprises stacking the green films on top of each other to form a green layer with a layer thickness of preferably a maximum of 130 μm.

Alternatively, a single thick green film can be provided. This is produced by film casting. Due to the manufacturing process, the film is then thicker but more inhomogeneous, with an additional longer drying time and generally also greater sintering shrinkage.

Another step comprises sintering the green layer at a maximum temperature of 1030° C. to obtain the piezoelectric layer.

A further step concerns the application of the piezoelectric layer to a carrier element and the material bonding to the carrier element so that the layer and the carrier element are mechanically coupled. The ratio of the thickness of the piezoelectric layer to the thickness of the carrier element is then preferably 0.127 to 1.3.

Preferably, the steps are carried out in the order mentioned. It is particularly preferred that the steps follow each other directly.

In one embodiment, green films are provided comprising a ceramic material having the composition (BiₓFeO₃)₁₋ₐ(Ba_{y}TiO₃)ₐ, where 0.20≤a≤0.50; 0.90≤x≤1.10 and 0.90≤y≤ 1.01.

A preferred layer thickness is between 50 and 150 micrometers. Preferably, no further layers are provided between the individual piezoelectric films, so that the green films lie directly on top of each other.

In one embodiment of the method, the green layer can be applied to a carrier element before sintering and sintered together with it. Due to the low sintering temperature, this method is also suitable for support elements that may not be processed at temperatures above 1030° C.

Producing the layer using the film technology described enables the layer to be produced with the desired thickness. There is no need for machining methods, which saves material. Due to the low sintering temperature, the method can be optimized in terms of energy.

In a preferred embodiment of the method, the sintering temperature is maintained for a maximum of 4 hours.

In a further preferred embodiment of the method, the sintering temperature is a maximum of 1000° C.

This means, for example, that the energy consumption and costs of the method can be reduced and the environmental compatibility of the method can be increased.

In one embodiment of the method, the green layer can be applied to a carrier element before sintering and sintered together with it. Due to the low sintering temperature, this method is also suitable for support elements that must not be processed at temperatures above 1000° C.

In a further preferred embodiment of the method, the sintering temperature is at least 900° C.

In further process steps, electrodes can be applied to the piezoelectric layer, preferably on two opposite surfaces of the layer. For example, the electrodes can be printed on.

In one embodiment, the piezoelectric layer can be applied to a carrier element, for example a membrane, and mechanically coupled to the carrier element. The component is then preferably designed in such a way that the carrier element and the piezoelectric layer deform together when stimulated.

Stimulating can consist in particular of applying an electric field to the piezoelectric layer.

The carrier element can be one of the electrodes. However, the carrier element can also be provided in addition to the electrodes. In particular, the piezoelectric layer with attached electrodes can be applied to the carrier element.

The carrier element and the piezoelectric layer can be bonded together by sintering.

The piezoelectric layer can also be bonded to the carrier element, for example by a bonding layer. The bonding layer can comprise an adhesive. The thickness of the bonding layer is preferably no more than 20 μm.

Further embodiments provide a method for producing a lead-free piezoelectric component with the piezoelectric layer described above, wherein the piezoelectric layer is applied to a carrier element and is bonded to the carrier element so that the layer and the carrier element are mechanically coupled.

In particular, the green layer can be applied to a carrier element before sintering and sintered with the carrier element. All previously mentioned embodiments and their features with their advantages apply analogously to this method.

Due to the low sintering temperature, this method is particularly suitable for carrier elements that must not be processed at high temperatures.

### BRIEF DESCRIPTION OF THE DRAWINGS

In the following, embodiments are described with reference to figures. The present invention is not limited to the embodiments shown.

FIG. 1 shows perspective view of a first embodiment of a piezoelectric component;

FIG. 2 shows detail view of the first embodiment of the piezoelectric component in cross-section;

FIG. 3 shows cross-sectional view of a second embodiment of a piezoelectric component as a haptic element;

FIG. 4 shows perspective view of a fourth embodiment of a piezoelectric component as a buzzer or ultrasonic transducer and

FIG. 5 shows schematic representation of the operation of a micropump for fluids.

### DETAILED DESCRIPTION OF ILLUSTRATIVE EMBODIMENTS

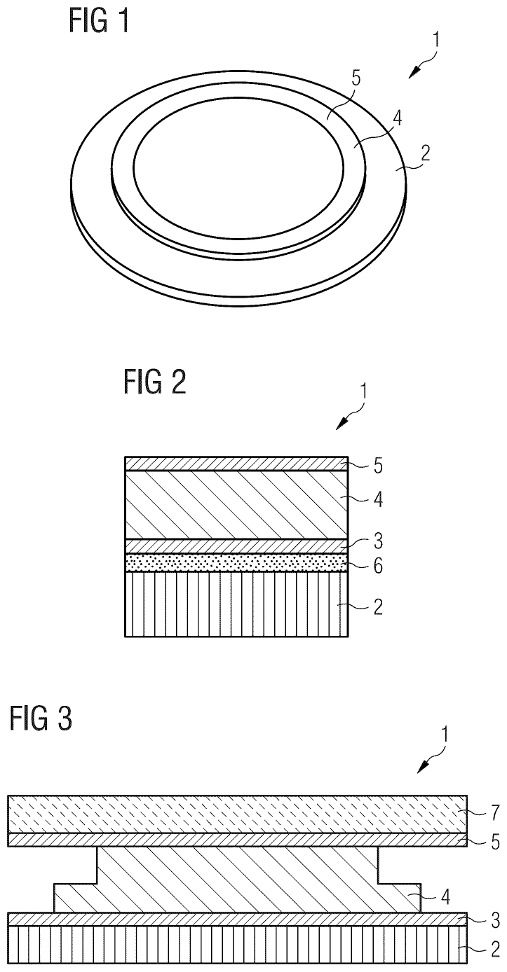

FIGS. 1 and 2 show a first exemplary piezoelectric component 1.

A piezoelectric element comprising, in this order, a first electrode 3, a piezoelectric ceramic layer 4 and a second electrode 5 is applied to a membrane 2 as a carrier element. In the embodiment example, the piezoelectric component 1 and the layers comprising it are designed as circular or elliptically formed disks.

The membrane 2 is preferably electrically conductive and comprises an electrically conductive material, for example a metal such as brass, aluminum, titanium, copper or a steel, a carbon fiber material, etc. Alternatively, the membrane 2 may comprise a plastic material which is metallized on the surface or which contains conductive particles.

The membrane 2 should be designed in such a way that it deforms depending on the deformation of the ceramic layer 4.

The membrane 2 preferably has a higher thickness and a higher diameter than the electrodes 3, 5 and the piezoelectric ceramic layer 4.

For example, the piezo element is attached to the diaphragm 2 using a connecting material 6 such as an adhesive.

The piezoelectric ceramic layer 3 is lead-free and comprises a material with the composition (BiₓFeO₃)₁₋ₐ(Ba_{y}TiO₃)ₐ. The indices are selected from the ranges 0.28≤a≤0.36; 0.99≤x≤1.05 and 0.975≤y≤1.005 and are, for example, a=0.305, x=1.030, y=0.995.

The piezoelectric ceramic layer 4 is designed and arranged in such a way that it deforms in response to a deformation of the membrane 2.

Preferably, exactly one piezoelectric ceramic layer 4 is provided in the piezoelectric component 1.

Compared to conventional piezoelectric ceramic layers, the described lead-free ceramic layer 4 has a significantly increased coercive field strength. In the example, the coercive field strength is E_{c}=1.9 kV/mm.

Due to the increased coercive field strength, the piezoelectric component 1 can be designed with a significantly thinner ceramic layer 4, for example 50 to 110 micrometers thick, compared to conventional components.

The production of the present ceramic layer 4 is therefore more material-efficient than the production of conventional ceramic layers.

The ceramic material described is sintered in an air atmosphere. Due to the comparatively low sintering temperature and the comparatively short holding time, the production of the described ceramic is more energy-efficient than the production of conventional ceramic layers.

The ceramic material described also has a comparatively high Curie temperature of 450° C. and a similar density of 7.4×10³ kg/m³ to conventional, non-lead-free piezoelectric materials.

The piezoelectric component 1 can be designed as a haptic element.

In one embodiment example, the haptic element can be designed as an actuator that transmits an electrical signal into a mechanical deflection of the diaphragm 2.

For this purpose, an electric field is applied to the piezoelectric ceramic layer 4. The piezoelectric layer deforms in response to the applied electric field. The piezoelectric ceramic layer 4, which is designed as a circular disc, bulges out of the neutral position, particularly in its middle. The neutral position is the position of the ceramic layer 4 when no electric field is applied.

In a further embodiment, the haptic element can be designed as a touch sensor.

For example, an additional cover 7 can be applied to the piezoelectric element as shown in FIG. 3. The cover 7 can, for example, be glued onto the piezoelectric element.

In particular, the touch sensor can be installed in a trackpad of a laptop computer, for example. The piezoelectric component 1 is then mounted directly under the touch-sensitive surface of the trackpad.

If pressure is exerted on the touch-sensitive surface of the trackpad, which in this case may correspond to the cover 7 on the piezoelectric element, the piezoelectric element arranged underneath is also deformed. In response to the deformation, an electrical voltage is generated in the piezoelectric layer 4, which is transmitted as an electrical signal to an electronic evaluation unit.

Similar touch sensors are also located behind cell phone screens, for example.

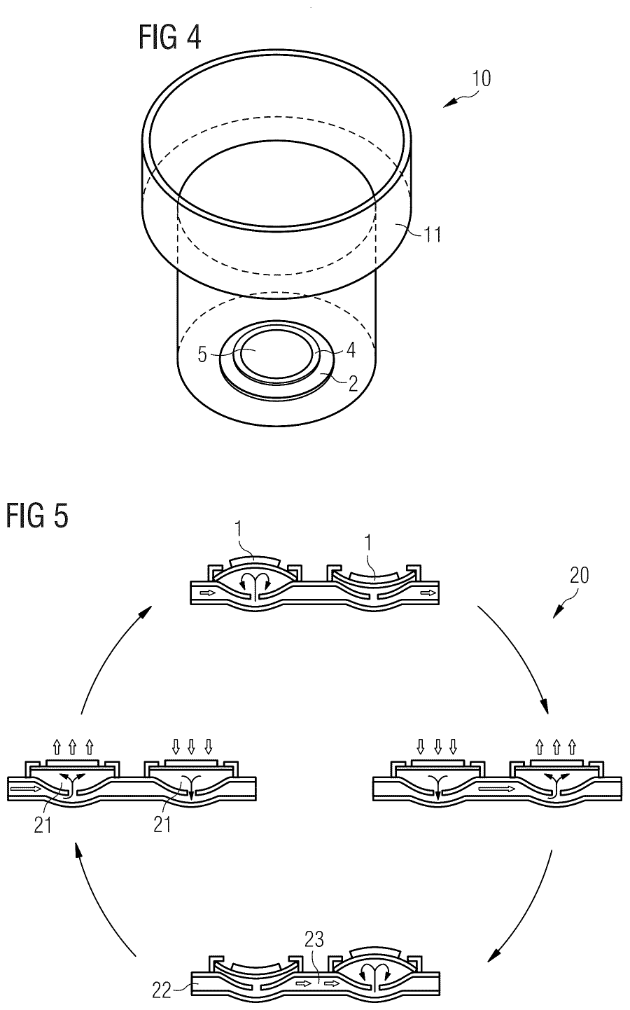

In a further embodiment, the piezoelectric component 1 can be designed as a buzzer 10, as shown in FIG. 4. A buzzer 10 essentially corresponds to a haptic element in its mode of operation. By applying a suitable, correspondingly high electrical frequency, a rapid and regular deformation of the piezoelectric element is caused and the membrane 2 coupled to it is thus stimulated to vibrate. A resonance chamber 11 surrounding the piezoelectric component 1 is provided to amplify the acoustic signal generated in this way.

The resonance chamber 11 can, for example, be an aluminum pot into which the piezoelectric component 1 is glued.

For example, the piezoelectric layer 4 is subjected to an electrical voltage of up to 3 volts and an electrical frequency of 4000 Hz in order to generate an acoustic signal with a volume of at least 75 decibels.

In another embodiment example, the piezoelectric component 1 is designed as an ultrasonic transducer 10. An ultrasonic transducer 10 is essentially similar in design to a buzzer 10. However, unlike a buzzer, the sound frequency generated is not in the audible range, but in the ultrasonic range.

Furthermore, the piezoelectric component 1 functions as an ultrasonic transducer 10 not only as an actuator that generates ultrasound, but also as a sensor that detects an ultrasonic signal. In particular, a reflected ultrasonic signal of the generated and emitted ultrasonic signal can be detected. The distance to a reflecting object can be determined from the duration between the transmission and detection of the reflected ultrasonic signal. Such an ultrasonic transducer can therefore be used as a distance sensor in automotive applications, for example.

In another embodiment example, shown in FIG. 5, the piezoelectric component 1 is used as an actuator of a micropump 20 for fluids. At least two piezoelectric components 1 are required for the construction of the pump. The piezoelectric components 1 form the covers of interconnected chambers 21. The chambers 21 are connected, for example, by a pipeline 22, which is suitable for pumping a fluid. Valves 23 in the pipeline indicate the flow direction of the fluid in advance. By deforming the piezoelectric element, the volume of the chambers 21 can be increased or reduced to create a stroke. For example, the volume of a first chamber 21 can be reduced, while the volume of a second chamber 21 following along the pipeline is increased, so that the fluid to be conveyed flows from the first to the second chamber 21.

Such a micropump 20 can be used, for example, for dosing fluids in the medical field.

In another embodiment example, the piezoelectric component 1 is used as a synthetic jet actuator, i.e. an actuator for generating an artificial jet. The principle is the same as for the application as a micropump 20. Such an actuator can be used, for example, for the targeted cleaning of sensitive surfaces such as transmission surfaces for optical and sensory surfaces.

In another embodiment, the piezoelectric component 1 can be used as a particle detector. The piezoelectric component 1 is installed in a flow channel for this purpose. For example, a gas that transports solid particles can be conveyed in the flow channel.

In the operating state, the piezoelectric layer 4 of the component is stimulated to oscillate at a frequency in the ultrasonic range.

If a solid particle hits a membrane 2 of the piezoelectric component 1, the piezoelectric layer 4 coupled to it deforms and causes a change in the oscillation frequency. The change in the oscillation frequency depends on the size and number of particles, which can therefore be determined by the evaluation electronics.

In another embodiment example, the piezoelectric component serves as a converter of mechanical energy to electrical energy, i.e. “energy harvesting”. This application therefore uses the opposite effect to the haptic actuator. If a piezoelectric layer 4 is deformed, an electrical potential is generated, which can be tapped by a suitable circuit and temporarily stored in the form of electrical energy, read out as a measured variable or used directly to send a signal.

Examples of applications include wireless sensors for light switches, footfall or closing detectors, vibration detectors or flow detectors.

In further embodiments, the piezoelectric component 1 described can be used to transmit energy and data through solid bodies by means of ultrasonic transmission. This communication is used to control and read sensors, actuators or for electronic identification. One piezoelectric component 1 serves as an ultrasonic transmitter and another as an ultrasonic receiver.

In alternative embodiments, the piezoelectric layer 4 may also comprise a piezoelectric plastic such as PVDF (polyvinylidene fluoride), in contrast to the examples described above. The layer may also comprise a ceramic material and a plastic.

1.-41. (canceled)

42. A piezoelectric component comprising:
a piezoelectric layer comprising a polycrystalline piezoelectric ceramic material with a coercive field strength of at least 1.8 kV/mm; and
a carrier element to which the piezoelectric layer is arranged and with which the piezoelectric layer is mechanically coupled.

43. The piezoelectric component according to claim 42, wherein an electromechanical coupling factor k31 of the piezoelectric ceramic material is 0.2 to 0.3.

44. The piezoelectric component according to claim 42, wherein a permittivity number εᵣ of the piezoelectric ceramic material is less than 1100.

45. The piezoelectric component according to claim 44, wherein the permittivity number εᵣ of the piezoelectric ceramic material is between 900 and 1000, inclusive.

46. The piezoelectric component according to claim 42, wherein a piezoelectric constant d31 of the piezoelectric ceramic material is at least 50 pm/V and at most 100 pm/V.

47. The piezoelectric component according to claim 42, wherein a Curie temperature of the piezoelectric ceramic material is between 400° C. and 500° C., inclusive.

48. The piezoelectric component according to claim 42, wherein a mechanical quality Qm of the piezoelectric ceramic material is between 50 and 100, inclusive.

49. The piezoelectric component according to claim 42, wherein a density of the piezoelectric ceramic material is between 7000 kg/m³ and 7500 kg/m³, inclusive.

50. The piezoelectric component according to claim 42, wherein a coercive field strength, an electromechanical coupling factor k31, a permittivity number εᵣ, a piezoelectric constant d31, a Curie temperature, a mechanical quality Qm, a density of the piezoelectric layer or several quantities corresponding to a corresponding quantity of the polycrystalline piezoelectric ceramic material.

51. The piezoelectric component according to claim 42, wherein the carrier element has a modulus of elasticity E between 100 GPa and 180 GPa, inclusive.

52. The piezoelectric component according to claim 42, wherein the piezoelectric layer comprises a ceramic material having a composition (BiₓFeO₃)₁₋ₐ(Ba_{y}TiO₃)ₐ, wherein 0.20≤a≤0.50 and 0.90≤x≤1.10 and 0.90≤y≤1.01.

53. The piezoelectric component according to claim 42, wherein a thickness of the piezoelectric layer is at least 40 μm and a ratio of the thickness of the piezoelectric layer to a thickness of the carrier element is 0.127 to 1.3.

54. The piezoelectric component according to claim 42, wherein each of the piezoelectric layer and the carrier element is disk-shaped and a ratio of a diameter of the piezoelectric layer to a diameter of the carrier element is 0.55 to 0.73.

55. The piezoelectric component according to claim 42, wherein a neutral phase of a component composite comprising the carrier element and the piezoelectric layer is located within the piezoelectric layer, the neutral phase here being designated as an imaginary line which does not undergo any deformation.

56. The piezoelectric component according to claim 42, wherein the piezoelectric component comprises exactly one piezoelectric layer.

57. The piezoelectric component according to claim 42, wherein the piezoelectric component is a haptic actuator configured to generate a mechanical deformation of the carrier element when an electrical signal is applied to the piezoelectric layer.

58. The piezoelectric component according to claim 57, wherein the piezoelectric layer is configured to receive a DC voltage of at least 50 volts and a tip-to-peak voltage of at least 700 volts.

59. The piezoelectric component according to claim 42, wherein the piezoelectric component is a haptic sensor configured to generate an electrical signal that can be picked up at the piezoelectric layer from a mechanical deformation of the carrier element.

60. The piezoelectric component according to claim 42, wherein the piezoelectric component is a buzzer configured to convert a periodic electrical signal applied to the piezoelectric layer into a mechanical vibration of the carrier element in an audible sound range.

61. The piezoelectric component according to claim 60, wherein the piezoelectric layer is configured such that the buzzer reaches a maximum sound pressure when stimulated by an electrical signal with a voltage of up to 3 volts and an electrical frequency of 4.0×10³ Hertz.

62. The piezoelectric component according to claim 42, wherein the piezoelectric component is an ultrasonic transducer configured to convert a periodic electrical signal applied to the piezoelectric layer into a mechanical vibration of the carrier element in an ultrasonic range and vice versa.

63. The piezoelectric component according to claim 42, wherein the piezoelectric component is a micropump for fluids.

64. The piezoelectric component according to claim 42, wherein the piezoelectric component is a particle detector.

65. The piezoelectric component according to claim 42, wherein the carrier element has electrically conductive properties, and wherein the carrier element is an electrode arranged at a surface of the piezoelectric layer.

66. The piezoelectric component according to claim 42, wherein the carrier element is bonded to the piezoelectric layer by soldering, welding, bonding with an adhesive material or by joint sintering.

67. The piezoelectric component according to claim 66, wherein the adhesive material is electrically non-conductive or anisotropically conductive or electrically conductive.

68. The piezoelectric component according to claim 42, wherein the piezoelectric component is a radial oscillator, and wherein a ratio of diameter to thickness of the piezoelectric layer is at least 10 or more.

69. The piezoelectric component according to claim 42, wherein the piezoelectric layer comprises a piezoelectric plastic.

70. The piezoelectric component according to claim 69, wherein the piezoelectric layer comprises polyvinylidene fluoride.

71. The piezoelectric component according to claim 69, wherein the piezoelectric layer comprises a composite material of a piezoelectric ceramic and a piezoelectric plastic.

72. The piezoelectric component according to claim 69, wherein the piezoelectric layer has a coercive field strength of up to 125 kV/mm.

73. The piezoelectric component according to claim 69, wherein the piezoelectric layer has a permittivity number &r greater than 8.

74. The piezoelectric component according to claim 42, wherein a ratio between a modulus of elasticity of the carrier element and a modulus of elasticity of the piezoelectric layer is between 0.0004 and 3000, inclusive.

75. The piezoelectric component according to claim 42, further comprising an electrode as a thin film between the piezoelectric layer and the carrier element.

76. The piezoelectric component according to claim 42, wherein the piezoelectric layer is not a thin film.

77. A piezoelectric component comprising:
a piezoelectric layer comprising a polycrystalline piezoelectric ceramic material with a coercive field strength of at least 1.8 kV/mm; and
a carrier element to which the piezoelectric layer is arranged and with which the piezoelectric layer is mechanically coupled,
wherein a thickness of the piezoelectric layer is at least 40 μm, and
wherein a ratio of the thickness of the piezoelectric layer to a thickness of the carrier element is 0.127 to 1.3.

78. A method for manufacturing a piezoelectric component having a piezoelectric layer, the method comprising:
providing at least one green film to produce a green layer with a layer thickness of at least 50 μm and a maximum of 150 μm;
sintering the green layer at a maximum temperature of 1050° C. to obtain the piezoelectric layer;
applying the piezoelectric layer to a carrier element; and
materially bonding the piezoelectric layer to the carrier element so that the piezoelectric layer and the carrier element are mechanically coupled.

79. The method according to claim 78, wherein a sintering temperature is maintained for a maximum of 4 hours.

80. The method according to claim 78, wherein a sintering temperature is at most 1000° C.

81. The method according to claim 78, wherein the green layer is applied to the carrier element before sintering, and wherein the green layer is sintered with the carrier element.

82. The method according to claim 78, wherein several green films are stacked on top of each other and pressed to produce the green layer.

83. The method according to claim 78, wherein the green layer comprises exactly one green film.

84. The method according to claim 78, wherein a sintered layer is poled in an external electric field to obtain the piezoelectric layer.

85. The method according to claim 78, further comprising bonding the carrier element and the piezoelectric layer via an adhesive layer, a solder layer or a metallic layer.

86. The method according to claim 85, wherein the adhesive layer is electrically non-conductive or anisotropically conductive or electrically conductive.
